(19) United States
(12) Patent Application Publication
(10) Pub. No.: US 2025/0318263 A1
(43) Pub. Date: Oct. 9, 2025

(54) ARRAY SUBSTRATE, PREPARATION METHOD FOR ARRAY SUBSTRATE, AND DISPLAY PANEL

(71) Applicants: Hefei Visionox Technology Co., Ltd., Hefei (CN); Yungu (Gu’an) Technology Co., Ltd., Langfang (CN)

(72) Inventors: Guowen YAN, Hefei (CN); Lin XU, Langfang (CN); Xiaoqi SUN, Langfang (CN); Yinghai MA, Langfang (CN); Lidong DING, Langfang (CN); Fa-Hsyang CHEN, Langfang (CN)

(73) Assignees: Hefei Visionox Technology Co., Ltd., Hefei (CN); Yungu (Gu’an) Technology Co., Ltd., Langfang (CN)

(21) Appl. No.: 19/242,872

(22) Filed: Jun. 18, 2025

(30) Foreign Application Priority Data
Jun. 28, 2024 (CN) 202410873264.1

(51) Int. Cl. H10D 86/40

(52) U.S. Cl. CPC H10D 86/423; H10D 86/451

(57) ABSTRACT

The present application provides an array substrate, a preparation method for an array substrate, and a display panel. The array substrate includes a substrate, a first insulation layer, a planarization layer, a semiconductor layer, a source layer, and a drain layer. The first insulation layer is disposed on one side of the substrate, and the planarization layer, the semiconductor layer, the source layer, and the drain layer are each disposed on a side of the first insulation layer away from the substrate. The source layer is electrically connected to the drain layer via the semiconductor layer. The semiconductor layer includes a first semiconductor sublayer, the first semiconductor sublayer includes at least a crystalline semiconductor material, and at least part of the first semiconductor sublayer is stacked on a side of the planarization layer facing away from the substrate.

### CROSS-REFERENCE TO RELATED APPLICATIONS

The present application claims priority to the Chinese Patent Application No. 202410873264.1, filed on Jun. 28, 2024, and the entire contents of the aforementioned application are hereby incorporated by reference in its entirety.

### FIELD

The present application relates to the field of display, and in particular, to an array substrate, a preparation method for an array substrate, and a display panel.

### BACKGROUND

At present, a thin film transistor (TFT) of an array substrate serves as a primary switching element in liquid crystal display panels and active matrix-driven organic electroluminescent display panels, and the performance of the thin film transistor directly affects the development of display panels.

However, a semiconductor layer of the existing thin film transistor has a low mobility, resulting in a high on-resistance between a source layer and a drain layer, which affects the performance of the thin film transistor and thus the performance of the display panel.

Therefore, there is an urgent need for a new array substrate, a preparation method for an array substrate, and a display panel.

### SUMMARY

An objective of the present application is to provide an array substrate, a preparation method for an array substrate, and a display panel, which can increase the mobility of a semiconductor layer so as to improve the performance of a thin film transistor and thus the performance of the display panel.

In a first aspect, the present application provides an array substrate, including: a substrate; a first insulation layer disposed on one side of the substrate; and a planarization layer, a semiconductor layer, a source layer and a drain layer which are disposed on a side of the first insulation layer away from the substrate, the source layer being electrically connected to the drain layer via the semiconductor layer, and the semiconductor layer including a first semiconductor sublayer, the first semiconductor sublayer including at least a crystalline semiconductor material, and the first semiconductor sublayer being stacked on a side of the planarization layer facing away from the substrate.

In a second aspect, the present application provides a preparation method for an array substrate. The preparation method includes:
providing a substrate;
forming a first insulation layer on one side of the substrate; and
forming a planarization layer, a semiconductor layer, a source layer and a drain layer on a side of the first insulation layer facing away from the substrate, the source layer being electrically connected to the drain layer via the semiconductor layer, and the semiconductor layer including a first semiconductor sublayer, the first semiconductor sublayer including at least a crystalline semiconductor material, and the first semiconductor sublayer being stacked on a side of the planarization layer facing away from the substrate.

In a third aspect, the present application provides a display panel including an array substrate in any of the above aspects.

The present application provides an array substrate, a preparation method for an array substrate, and a display panel. The array substrate includes a substrate, a first insulation layer, a planarization layer, a semiconductor layer, a source layer, and a drain layer. The first insulation layer is disposed on one side of the substrate, and the planarization layer, the semiconductor layer, the source layer, and the drain layer are each disposed on a side of the first insulation layer away from the substrate. The source layer is electrically connected to the drain layer via the semiconductor layer. The semiconductor layer includes a first semiconductor sublayer, the first semiconductor sublayer includes at least a crystalline semiconductor material, and at least part of the first semiconductor sublayer is stacked on a side of the planarization layer facing away from the substrate. In this way, at least part of the first semiconductor sublayer can be grown on a flat surface of the planarization layer, so as to improve the crystallization effect of the first semiconductor sublayer, increase the mobility of the semiconductor layer, reduce the on-resistance between the source layer and the drain layer, and increase the on-current between the source layer and the drain layer, thereby improving the performance of the thin film transistor and the performance of the display panel.

### BRIEF DESCRIPTION OF THE DRAWINGS

FIG. 1 is a schematic cross-sectional view of an array substrate according to some embodiments of the present application;

FIG. 2 is an enlarged view of part A in FIG. 1;

FIG. 3 is another schematic cross-sectional view of an array substrate according to some embodiments of the present application;

FIG. 4 is yet another schematic cross-sectional view of an array substrate according to some embodiments of the present application;

FIG. 5 is still another schematic cross-sectional view of an array substrate according to some embodiments of the present application;

FIG. 6 is a flowchart of a method for preparing an array substrate according to some embodiments of the present application;

FIG. 7 is another flowchart of a method for preparing an array substrate according to some embodiments of the present application; and

FIG. 8 is yet another flowchart of a method for preparing an array substrate according to some embodiments of the present application.

Reference numerals in the drawings are as follows:

### LIST OF REFERENCE NUMERALS

Substrate 10; First insulation layer 20; Planarization layer 30; Semiconductor layer 40; First semiconductor sublayer 41; Second semiconductor sublayer 42; Source layer 50; Drain layer 60; First gate layer 70; Second gate layer 80; Second insulation layer 90.

### DETAILED DESCRIPTION OF THE EMBODIMENTS

In some array substrates, a source layer and a drain layer of a thin film transistor are electrically connected via a semiconductor layer. Therefore, increasing the mobility of the semiconductor layer can reduce the on-resistance between the source layer and the drain layer and increase the on-current between the source layer and the drain layer, so that it is possible to reduce the size of the thin film transistor to a certain extent or increase the luminance of a light-emitting unit when turned on by the thin film transistor, to improve the performance of the thin film transistor and the display panel. At present, a crystalline semiconductor material can be used to prepare a semiconductor layer to increase the mobility of the semiconductor layer. However, the semiconductor layer is usually disposed on a first insulation layer on one side of the substrate. Since a surface of the substrate typically exhibits large undulation, a surface of the first insulation layer away from the substrate has large undulation, which affects the crystallization effect of the semiconductor layer and results in low mobility.

The embodiments of the present application provide an array substrate applied to a display panel. The display panel may be an organic light-emitting diode (OLED) display panel, or another type of display panel, such as a micro light emitting diode (Micro-LED) display panel or a quantum dot light emitting diode (QLED) display panel.

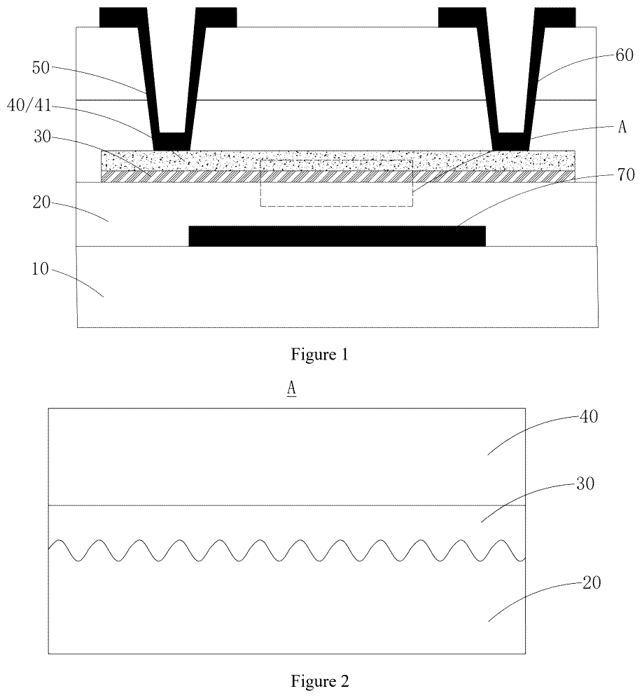

Referring to FIGS. 1 and 2, in a first aspect, the present application provides an array substrate, including a substrate 10, a first insulation layer 20 disposed on one side of the substrate 10, and a planarization layer 30, a semiconductor layer 40, a source layer 50 and a drain layer 60 which are disposed on a side of the first insulation layer 20 away from the substrate 10. The source layer 50 is electrically connected to the drain layer 60 via the semiconductor layer 40, and the semiconductor layer 40 includes a first semiconductor sublayer 41. The first semiconductor sublayer 41 includes at least a crystalline semiconductor material, and the first semiconductor sublayer 41 is stacked on a side of the planarization layer 30 facing away from the substrate 10.

The substrate 10 may be a rigid substrate made of glass, plastic, etc., or a flexible substrate made of polyethersulfone (PES), polyacrylate (PAR), polyetherimide (PEI), polyethylene naphthalate (PEN), polyethylene terephthalate (PET), polyphenylene sulfide (PPS), polyarylate, polyimide (PI), polycarbonate (PC), cellulose acetate propionate (CAP), etc. The first insulation layer 20 may serve the function of insulation between the substrate 10 and the semiconductor layer 40 to isolate the substrate 10 from the semiconductor layer 40. The semiconductor layer 40 includes a first semiconductor sublayer 41, and the first semiconductor sublayer 41 includes at least a crystalline semiconductor material which, as compared with a first semiconductor sublayer 41 prepared from an amorphous semiconductor material, can increase the mobility of the first semiconductor sublayer 41 to a certain extent, that is, increase the mobility of the semiconductor layer 40. The source layer 50 is electrically connected to the drain layer 60 via the semiconductor layer 40. Therefore, increasing the mobility of the semiconductor layer 40 can reduce the on-resistance between the source layer 50 and the drain layer 60 and increase the on-current between the source layer 50 and the drain layer 60, to improve the performance of the thin film transistor and the display panel. The planarization layer 30 is disposed between the first insulation layer 20 and the first semiconductor sublayer 41, and may provide a flat surface for preparing the first semiconductor sublayer 41, thereby improving the crystallization effect of the first semiconductor sublayer 41 to further increase the mobility of the first semiconductor sublayer 41.

In the array substrate according to the present application, the first insulation layer 20 is disposed on one side of the substrate 10, and the planarization layer 30, the semiconductor layer 40, the source layer 50, and the drain layer 60 are each disposed on a side of the first insulation layer 20 away from the substrate 10. The source layer 50 is electrically connected to the drain layer 60 via the semiconductor layer 40. The semiconductor layer 40 includes a first semiconductor sublayer 41. The first semiconductor sublayer 41 includes at least a crystalline semiconductor material, and at least part of the first semiconductor sublayer 41 is stacked on a side of the planarization layer 30 facing away from the substrate 10, so that at least part of the first semiconductor sublayer 41 grows on the flat surface of the planarization layer 30, so as to improve the crystallization effect of the first semiconductor sublayer 41, increase the mobility of the semiconductor layer 40, reduce the on-resistance between the source layer 50 and the drain layer 60, and increase the on-current between the source layer 50 and the drain layer 60, thereby improving the performance of the thin film transistor and the performance of the display panel.

In some embodiments, a material of the planarization layer 30 includes a wide-bandgap semiconductor material.

In particular, the wide-bandgap semiconductor material refers to a semiconductor material having a bandgap of 2.3 eV or greater. The material of the planarization layer 30 includes a wide-bandgap semiconductor material, which can increase the turn-on voltage of the planarization layer 30, so that the planarization layer 30 can effectively isolate the semiconductor layer 40 from a film layer below the planarization layer 30 during the subsequent processing of the array substrate to prevent electrons or impurities in the film layer below the planarization layer from entering the semiconductor layer 40, so as to avoid affecting the performance of the semiconductor layer 40.

In one embodiment, the material of the planarization layer 30 may include at least one of GaOx, GaZnxOy, GeOx, NbOx, and PrOx to increase the turn-on voltage of the planarization layer 30 to improve the isolating effect of the planarization layer 30.

Referring to FIG. 1, in one embodiment, the planarization layer 30 includes a first pattern, the semiconductor layer 40 includes a second pattern, and the first pattern is the same as the second pattern. Therefore, the planarization layer 30 and the semiconductor layer 40 can be patterned using the same mask, or during a wet etching process for patterning the semiconductor layer 40, an etching solution can etch the planarization layer 30 after etching the semiconductor layer 40, thereby simplifying the process steps and reducing the process complexity.

In some embodiments, the material of the planarization layer 30 includes an insulating material, which can further isolate the semiconductor layer 40 from the film layer below the planarization layer 30, preventing the semiconductor layer 40 from being affected by the film layer below the planarization layer 30.

In one embodiment, the material of the planarization layer 30 includes at least one of SiOx, AlOx, HfOx, SiOxNy, and SiNx to ensure the isolation effect of the planarization layer 30.

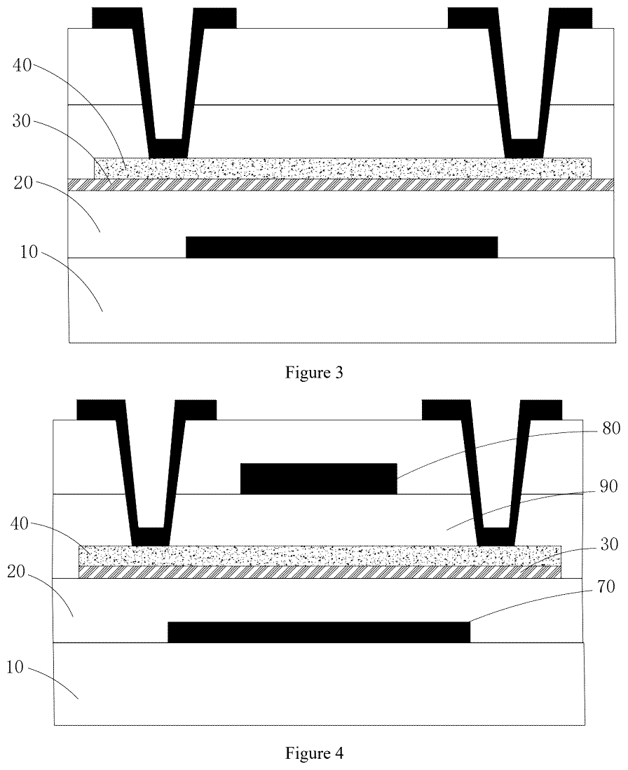

Referring to FIG. 3, in one embodiment, the planarization layer 30 is provided as an entire layer, that is, the orthographic projection of the planarization layer 30 on the substrate 10 overlaps with the orthographic projection of the first insulation layer 20 on the substrate 10, to further ensure the isolating effect of the planarization layer 30. Moreover, there is no need for additional processing for the planarization layer 30, which can reduce the process complexity.

In some embodiments, a plurality of protrusions are formed on a surface of a side of the planarization layer 30 away from the substrate 10, and have a height in a direction perpendicular to the substrate 10 satisfying H≤3 nm, to ensure the flatness of the surface of the side of the planarization layer 30 away from the substrate 10, so that the semiconductor layer 40 can be grown on a relatively flat surface, thereby improving the crystalline effect of the semiconductor layer 40.

In one embodiment, the height of the protrusions in the direction perpendicular to the substrate 10 may be 3 nm, 2 nm, 1.5 nm, 1 nm, 0.7 nm, 0.5 nm, or any other value within the above range. Ideally, the height of the protrusions may be 0, so as to achieve optimal flatness of the surface of the side of the planarization layer 30 away from the substrate 10.

In one embodiment, the height satisfies H≤1 nm, to further improve the flatness of the surface of the side of the planarization layer 30 away from the substrate 10. The height of the protrusions in the direction perpendicular to the substrate 10 may be 1 nm, 0.6 nm, 0.4 nm, 0.2 nm, or any other value within the above range.

It is to be noted that, since the semiconductor layer 40 is disposed on the planarization layer 30, the surface of the side of the semiconductor layer 40 away from the substrate 10 has protruding portions the same as the above protrusions on the surface of the side of the planarization layer 30 away from the substrate 10. The height of the protruding portion in the direction perpendicular to the substrate 10 is less than or equal to 1 nm.

Still referring to FIG. 1, in some embodiments, the array substrate further includes a first gate layer 70. The first gate layer 70 is disposed between the substrate 10 and the first insulation layer 20 to form a bottom-gate thin film transistor. In this case, the first gate layer 70 and the first insulation layer 20 simultaneously serve as optical protective layers to reduce the generation of photogenerated carriers, to improve the stability of the thin film transistor.

Referring to FIG. 4, in one embodiment, the array substrate further includes a second gate layer 80 and a second insulation layer 90. The second insulation layer 90 is disposed on a side of the semiconductor layer 40 facing away from the substrate 10, and the second gate layer 80 is stacked on a side of the second insulation layer 90 facing away from the substrate 10, so as to form a double-gate thin film transistor, thereby improving the stability of the transistor.

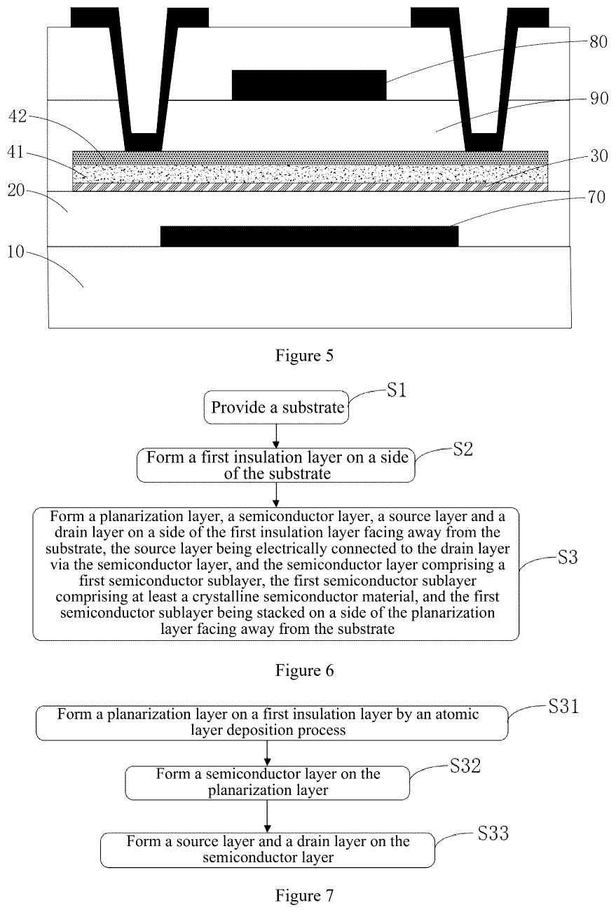

Referring to FIG. 5, in some embodiments, the semiconductor layer 40 further includes a second semiconductor sublayer 42. The second semiconductor sublayer 42 is disposed on a side of the first semiconductor sublayer 41 facing away from the substrate 10, and the second semiconductor sublayer 42 has a mobility lower than the mobility of the first semiconductor sublayer 41.

The second semiconductor sublayer 42 may be made of a crystalline semiconductor material or an amorphous semiconductor material, as long as the mobility of the second semiconductor sublayer is lower than the mobility of the first semiconductor sublayer 41.

In this embodiment, the second semiconductor sublayer 42 is disposed on the first semiconductor sublayer 41, and the mobility of the second semiconductor sublayer 42 is lower than the mobility of the first semiconductor sublayer 41, so that when the thin film transistor is turned on, the first semiconductor sublayer 41 and the second semiconductor sublayer 42 can be activated simultaneously, and two channels are formed between the source layer 50 and the drain layer 60 for conduction of currents, thereby further increasing the mobility of the semiconductor layer 40.

In one embodiment, a thickness D1 of the first semiconductor sublayer 41 in the direction perpendicular to the substrate 10 may satisfy 3 nm≤D1≤25 nm, and a thickness D2 of the second semiconductor sublayer 42 in the direction perpendicular to the substrate 10 may satisfy 3 nm≤D2≤20 nm. Therefore, by appropriately setting the thicknesses of the first semiconductor sublayer 41 and the second semiconductor sublayer 42, the mobility of the semiconductor layer 40 can be adjusted to a certain extent.

In one embodiment, a material of the second semiconductor sublayer 42 includes at least an amorphous semiconductor material, and the second semiconductor sublayer 42 is configured to be at least partially crystallizable under the induction of the first semiconductor sublayer 41.

In particular, the amorphous semiconductor material is in an amorphous state, and has a mobility lower than the mobility of the crystalline semiconductor material.

Therefore, the mobility of the second semiconductor sublayer 42 is lower than the mobility of the first semiconductor sublayer 41. The second semiconductor sublayer 42 and the first semiconductor sublayer 41 may include the same elements, so that the second semiconductor sublayer 42 is at least partially crystallizable under the induction of the first semiconductor sublayer 41.

It is should be understood that since the first semiconductor sublayer 41 is grown on the flat surface of the planarization layer 30, the surface of the side of the first semiconductor sublayer 41 facing away from the substrate 10 is also a relatively flat surface, that is, the second semiconductor sublayer 42 can be grown on the flat surface of the side of the first semiconductor sublayer 41 facing away from the substrate 10, which facilitates the crystallization of the second semiconductor sublayer 42 induced by the first semiconductor sublayer 41, to increase the mobility of the semiconductor layer 40.

In this embodiment, by appropriately setting the material of the second semiconductor sublayer 42, the mobility of the second semiconductor sublayer 42 is lower than the mobility of the crystalline first semiconductor sublayer 41, and it is also convenient for the at least partial crystallization of the second semiconductor sublayer 42 under the induction of the first semiconductor sublayer 41, to further increase the mobility of the second semiconductor sublayer.

In one embodiment, the material of the first semiconductor sublayer 41 and the material of the second semiconductor sublayer 42 both include indium-gallium oxide, which is convenient for the at least partial crystallization of the second semiconductor sublayer 42 under the induction of the first semiconductor sublayer 41 while ensuring the performance of the first semiconductor sublayer 41 and the second semiconductor sublayer 42.

In one embodiment, the material of the first semiconductor sublayer 41 includes indium gallium oxide to ensure the performance of the first semiconductor sublayer 41.

In one embodiment, an indium content θ_{In2} in the first semiconductor sublayer 41 satisfies 60%≤θ_{In2}<100%, and a gallium content θ_{Ga2} satisfies 0<θ_{Ga2}≤40%. Therefore, by appropriately setting the content of each element in the first semiconductor sublayer 41, the crystallinity of the first semiconductor sublayer 41 is improved, so as to further increase the mobility thereof.

In particular, in the first semiconductor sublayer 41, the indium content may be 60%, 70%, 80%, 90%, 99%, or any other value within the above range, and the gallium content may be 10%, 20%, 30%, 40%, or any other value within the above range, which are not specifically limited in this embodiment.

In one embodiment, the material of the first semiconductor sublayer 41 further includes a first doping material. The first doping material includes at least Sn, so as to further improve the performance of the first semiconductor sublayer 41.

In one embodiment, a content θ₂ of the first doping material of the first semiconductor sublayer 41 satisfies 0≤θ₂≤30%. Therefore, by appropriately setting the content of the first doping material of the first semiconductor sublayer 41, the performance of the first semiconductor sublayer 41 is optimized. For example, the content of the first doping material of the first semiconductor sublayer 41 may be 0, or may be 10%, 15%, 20%, 25%, 30%, or any other value within the above range, which is not specifically limited in this embodiment.

In one embodiment, the material of the second semiconductor sublayer 42 includes at least indium gallium zinc oxide, so as to ensure the performance of the second semiconductor sublayer 42.

It should be noted that the material of the first semiconductor sublayer 41 and the material of the second semiconductor sublayer 42 may further include other compounds to further improve the performance of the first semiconductor sublayer 41 and the second semiconductor sublayer 42.

In one embodiment, an indium content θ_{In1} in the second semiconductor sublayer 42 satisfies 30%≤θ_{In1}≤70%, a gallium content θ_{Ga1} satisfies 0<θ_{Ga1}≤40%, and a zinc content θ_{Zn} satisfies 0<θ_{Zn}≤40%. Therefore, by appropriately setting the content of each element in the second semiconductor sublayer 42, the mobility of the second semiconductor sublayer 42 can be increased while satisfying the condition that the mobility of the second semiconductor sublayer 42 is lower than the mobility of the first semiconductor sublayer 41, and it is also convenient for the at least partial crystallization of the second semiconductor sublayer 42 under the induction of the first semiconductor sublayer 41.

In particular, in the second semiconductor sublayer 42, the indium content may be 30%, 40%, 50%, 65%, 70%, or any other value within the above range, the gallium content may be 10%, 20%, 30%, 40%, or any other value within the above range, and the zinc content may be 10%, 20%, 30%, 40%, or any other value within the above range, which are not specifically limited in this embodiment.

In one embodiment, the material of the second semiconductor sublayer 42 further includes a second doping material. The second doping material includes one or more of Ge, Sn, Nb, Pr and Al, to further improve the performance of the second semiconductor sublayer 42.

In one embodiment, the content θ₁ of the second doping material of the second semiconductor sublayer 42 satisfies 0≤θ₁≤20%. That is, the content of the second doping material of the second semiconductor sublayer 42 may be 0, or 10%, 15%, 20%, or a value within the above range. Therefore, by appropriately setting the content of the second doping material of the second semiconductor sublayer 42, the performance of the second semiconductor sublayer 42 can be optimized.

Referring to FIG. 6, in a second aspect, the present application provides a preparation method for an array substrate. The preparation method includes the following steps.
At S1, a substrate 10 is provided. The substrate 10 may be a flexible substrate 10 or a rigid substrate 10, which is not limited in this embodiment.
At S2, a first insulation layer 20 is formed on one side of the substrate 10. The first insulation layer 20 may cover the first gate layer 70. Part of the first insulation layer is located on the side of the first gate layer 70 facing away from the substrate 10, and the other part thereof extends to the side face of the first gate layer 70 in a direction parallel to the substrate 10 and may cover one side of the substrate 10. The first insulation layer 20 may be formed by a plasma-enhanced chemical vapor deposition process.
At S3, a planarization layer 30, a semiconductor layer 40, a source layer 50 and a drain layer 60 are formed on a side of the first insulation layer 20 facing away from the substrate 10. The source layer 50 is electrically connected to the drain layer 60 via the semiconductor layer 40, and the semiconductor layer 40 includes a first semiconductor sublayer 41. The first semiconductor sublayer 41 includes at least a crystalline semiconductor material, and the first semiconductor sublayer 41 is stacked on a side of the planarization layer 30 facing away from the substrate 10.

Specifically, the planarization layer 30 may be first prepared on one side of the substrate 10, and then the semiconductor layer 40 is prepared on the flat surface of the side of the planarization layer 30 facing away from the substrate 10, such that at least part of the first semiconductor sublayer 41 is stacked on the side of the planarization layer 30 facing away from the substrate 10. After the semiconductor layer 40 is prepared, the source layer 50 and the drain layer 60 may be formed on the semiconductor layer 40, and the source layer 50 is electrically connected to the drain layer 60 via the semiconductor layer 40. Since the semiconductor layer 40 is formed on the flat surface of the planarization layer 30, the flatness of the first semiconductor sublayer 41 can be improved by the planarization layer 30, which is convenient for the crystallization of the first semiconductor sublayer 41 during the preparation process to improve the crystallization effect thereof, so as to increase the mobility of the semiconductor layer 40, reduce the on-resistance between the source layer 50 and the drain layer 60, and increase the on-current between the source layer 50 and the drain layer 60, thereby improving the performance of the thin film transistor and the performance of the display panel.

Before the step of forming a first insulation layer 20 on one side of the substrate 10, the preparation method further includes the step of forming a first gate layer 70 on one side of the substrate 10. During the process of forming the first gate layer 70, a gate material may first be deposited on one side of the substrate 10, and the gate material is then patterned to form the first gate layer 70.

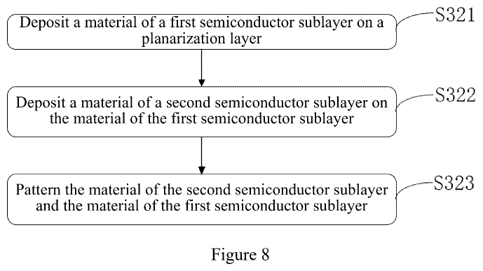

Referring to FIG. 7, in some embodiments, the step of forming a planarization layer 30, a semiconductor layer 40, a source layer 50 and a drain layer 60 on a side of the first insulation layer 20 facing away from the substrate 10 includes the following steps.
At S31, the planarization layer 30 is formed on the first insulation layer 20 by an atomic layer deposition process.
At S32, the semiconductor layer 40 is formed on the planarization layer 30. The semiconductor layer 40 is formed by a vapor deposition process. During the preparation process, the material of the first semiconductor sublayer 41 may first be deposited on the planarization layer 30, and the material of the first semiconductor sublayer is patterned to form a first semiconductor sublayer 41; and then the material of the second semiconductor sublayer 42 is deposited on the first semiconductor sublayer 41, and the material of the second semiconductor sublayer 42 is patterned to form a second semiconductor sublayer 42. In one embodiment, the material of the first semiconductor sublayer 41 and the material of the second semiconductor sublayer 42 may first be deposited sequentially on the planarization layer 30, and then the material of the second semiconductor sublayer 42 and the material of the first semiconductor sublayer 41 are patterned sequentially to form a first semiconductor sublayer 41 and a second semiconductor sublayer 42.
At S33, the source layer 50 and the drain layer 60 are formed on the semiconductor layer 40.

In this embodiment, the planarization layer 30 is formed by an atomic layer deposition process, which allows precise control over the ratio of elements in the planarization layer 30, thereby forming the planarization layer 30 with a flat surface while maintaining good performance of the planarization layer 30.

Referring to FIG. 8, in some embodiments, the step of forming a semiconductor layer 40 on the planarization layer 30 includes the following steps.
At S321, a material of a first semiconductor sublayer 41 is deposited on the planarization layer 30.
At S322, a material of a second semiconductor sublayer 42 is deposited on the material of the first semiconductor sublayer 41.
At S323, the material of the second semiconductor sublayer 42 and the material of the first semiconductor sublayer 41 are patterned.

In this embodiment, the material of the first semiconductor sublayer 41 and the material of the second semiconductor sublayer 42 are deposited sequentially on the planarization layer 30, and then the material of the second semiconductor sublayer 42 and the material of the first semiconductor sublayer 41 are sequentially patterned. Compared with the method in which the material of the first semiconductor sublayer 41 is first deposited and patterned to form the first semiconductor sublayer 41, and the material of the second semiconductor sublayer 42 is then deposited and the material of the second semiconductor sublayer 42 is patterned to form the second semiconductor sublayer 42, the array substrate does not need to switch repeatedly between the deposition process and the patterning process, thereby improving the production efficiency.

In one embodiment, the step of depositing a material of a first semiconductor sublayer 41 on the planarization layer 30 includes: depositing the material of the first semiconductor sublayer 41 on the planarization layer 30 by an atomic layer deposition process.

In this embodiment, the material of the first semiconductor sublayer 41 is deposited on the planarization layer 30 by an atomic layer deposition process, so that precise control over the ratio of elements in the first semiconductor sublayer 41 can be achieved, to improve the performance of the first semiconductor sublayer 41.

In one embodiment, the step of depositing a material of a second semiconductor sublayer 42 on the material of the first semiconductor sublayer 41 includes: depositing the material of the second semiconductor sublayer 42 on the material of the first semiconductor sublayer 41 by an atomic layer deposition process.

In this embodiment, the material of the second semiconductor sublayer 42 is deposited on the material of the first semiconductor sublayer 41 by an atomic layer deposition process, so that precise control over the ratio of elements in the second semiconductor sublayer 42 can be achieved, to improve the performance of the second semiconductor sublayer 42. In addition, the planarization layer 30, the material of the first semiconductor sublayer 41, and the material of the second semiconductor sublayer 42 can be formed by one process, thereby simplifying the process steps and improving the production efficiency.

In some embodiments, the step of patterning the material of the second semiconductor sublayer 42 and the material of the first semiconductor sublayer 41 includes:

patterning the material of the second semiconductor sublayer 42 and the material of the first semiconductor sublayer 41 by a wet etching process.

When the planarization layer 30 includes a wide-bandgap semiconductor material, the etching solution may also etch the planarization layer 30 beneath the material of the first semiconductor sublayer 41 while etching the material of the first semiconductor sublayer 41 and the material of the second semiconductor sublayer 42, so that the patterning of the planarization layer 30 is achieved, without the need for an additional process to pattern the planarization layer 30, thereby simplifying the process steps and improving the production efficiency.

In a third aspect, the present application provides a display panel including an array substrate in any of the above aspects.

What is claimed is:

1. An array substrate, comprising:
a substrate;
a first insulation layer disposed on one side of the substrate; and
a planarization layer, a semiconductor layer, a source layer and a drain layer which are disposed on a side of the first insulation layer away from the substrate, wherein the source layer is electrically connected to the drain layer via the semiconductor layer, and the semiconductor layer comprises a first semiconductor sublayer, the first semiconductor sublayer comprising at least a crystalline semiconductor material, and the first semiconductor sublayer being stacked on a side of the planarization layer facing away from the substrate.

2. The array substrate according to claim 1, wherein a material of the planarization layer comprises a wide-bandgap semiconductor material.

3. The array substrate according to claim 2, wherein the planarization layer comprises a first pattern, and the semiconductor layer comprises a second pattern, the first pattern being the same as the second pattern.

4. The array substrate according to claim 1, wherein a material of the planarization layer comprises an insulating material.

5. The array substrate according to claim 1, wherein an orthographic projection of the planarization layer on the substrate overlaps with an orthographic projection of the first insulation layer on the substrate.

6. The array substrate according to claim 1, wherein a surface of a side of the planarization layer away from the substrate comprises a plurality of protrusions which have a height in a direction perpendicular to the substrate satisfying H≤3 nm.

7. The array substrate according to claim 1, further comprising a first gate layer disposed between the substrate and the first insulation layer.

8. The array substrate according to claim 7, further comprising a second gate layer and a second insulation layer, the second insulation layer being disposed on a side of the semiconductor layer facing away from the substrate, and the second gate layer being stacked on a side of the second insulation layer facing away from the substrate.

9. The array substrate according to claim 1, wherein the semiconductor layer further comprises a second semiconductor sublayer disposed on a side of the first semiconductor sublayer facing away from the substrate, the second semiconductor sublayer having a mobility lower than the mobility of the first semiconductor sublayer.

10. The array substrate according to claim 9, wherein a material of the second semiconductor sublayer comprises at least an amorphous semiconductor material, and the second semiconductor sublayer is configured to be at least partially crystallizable under the induction of the first semiconductor sublayer.

11. The array substrate according to claim 9, wherein a material of the first semiconductor sublayer and the material of the second semiconductor sublayer each comprise indium-gallium oxide.

12. The array substrate according to claim 11, wherein the material of the first semiconductor sublayer comprises at least indium gallium oxide, and the first semiconductor sublayer has an indium content θ_{In2} satisfying 60%≤θ_{In2}<100%, and a gallium content θ_{Ga2} satisfying 0<θ_{Ga2}≤40%.

13. The array substrate according to claim 11, wherein the material of the first semiconductor sublayer further comprises a first doping material, the first doping material comprising at least Sn, and the first doping material of the first semiconductor sublayer having a content θ₂ satisfying 0≤θ₂≤30%.

14. The array substrate according to claim 11, wherein the material of the second semiconductor sublayer comprises at least indium gallium zinc oxide, and the second semiconductor sublayer has an indium content θ_{In1} satisfying 30%≤θ_{In1}≤70%, a gallium content θ_{Ga1} satisfying 0<θ_{Ga1}≤40%, and a zinc content θ_{Zn} satisfying 0<θ_{Zn}≤40%.

15. The array substrate according to claim 11, wherein the material of the second semiconductor sublayer further comprises a second doping material, the second doping material comprising one or more of Ge, Sn, Nb, Pr and Al, and the second doping material of the second semiconductor sublayer having a content θ₁ satisfying 0≤θ₁≤20%.

16. A preparation method for an array substrate, the preparation method comprising:
providing a substrate;
forming a first insulation layer on one side of the substrate; and
forming a planarization layer, a semiconductor layer, a source layer and a drain layer on a side of the first insulation layer facing away from the substrate, the source layer being electrically connected to the drain layer via the semiconductor layer, and the semiconductor layer comprising a first semiconductor sublayer, the first semiconductor sublayer comprising at least a crystalline semiconductor material, and the first semiconductor sublayer being stacked on a side of the planarization layer facing away from the substrate.

17. The preparation method according to claim 16, wherein the step of forming a planarization layer, a semiconductor layer, a source layer and a drain layer on a side of the first insulation layer facing away from the substrate comprises:
forming the planarization layer on the first insulation layer by an atomic layer deposition process;
forming the semiconductor layer on the planarization layer; and
forming the source layer and the drain layer on the semiconductor layer.

18. The preparation method according to claim 17, wherein the step of forming the semiconductor layer on the planarization layer comprises:
depositing a material of the first semiconductor sublayer on the planarization layer;
depositing a material of a second semiconductor sublayer on the material of the first semiconductor sublayer; and
patterning the material of the second semiconductor sublayer and the material of the first semiconductor sublayer.

19. The preparation method according to claim 18, wherein the step of depositing a material of the first semiconductor sublayer on the planarization layer comprises: depositing the material of the first semiconductor sublayer on the planarization layer by an atomic layer deposition process; and
the step of depositing a material of a second semiconductor sublayer on the material of the first semiconductor sublayer comprises: depositing the material of the second semiconductor sublayer on the material of the first semiconductor sublayer by an atomic layer deposition process.

20. A display panel, comprising:
an array substrate, comprising:
a substrate;
a first insulation layer disposed on one side of the substrate; and
a planarization layer, a semiconductor layer, a source layer and a drain layer which are disposed on a side of the first insulation layer away from the substrate, wherein the source layer is electrically connected to the drain layer via the semiconductor layer, and the semiconductor layer comprises a first semiconductor sublayer, the first semiconductor sublayer comprising at least a crystalline semiconductor material, and the first semiconductor sublayer being stacked on a side of the planarization layer facing away from the substrate.
